(19) United States
(12) Patent Application Publication
(10) Pub. No.: US 2018/0367228 A1
(43) Pub. Date: Dec. 20, 2018

(54) AUDIO PROCESSING UNIT

(71) Applicant: AfterMaster, Inc., Scottsdale, AZ (US)

(72) Inventors: Lawrence G. Ryckman, Scottsdale, AZ (US); Sheldon G. Yakus, Minden, NV (US)

(73) Assignee: AfterMaster, Inc., Scottsdale, AZ (US)

(21) Appl. No.: 16/114,378

(22) Filed: Aug. 28, 2018

Related U.S. Application Data
(63) Continuation-in-part of application No. 15/091,595, filed on Apr. 6, 2016, now Pat. No. 10,063,969.
(60) Provisional application No. 62/143,253, filed on Apr. 6, 2015.

(51) Int. Cl. H04H 60/04; H04R 3/04; G06F 3/16; H03G 5/16; H03G 7/06

(52) U.S. Cl. CPC H04H 60/04; H04R 3/04; H04R 5/04; H03G 5/165; H03G 7/06; G06F 3/165

(57) ABSTRACT

The present invention provides an audio processing unit having a microchip for processing an inputted audio signal. The microchip operates by duplicating the inputted audio signal, splitting the duplicated signal into at least two exact duplicates of the original inputted signal, layering the signals, processing the layers, and recombining the layers to provide an enhanced or processed audio signal. Thereafter, the processed audio file may be further processed by a user by utilizing any number of knobs, buttons, and the like disposed on the unit. Preferably, the unit is mountable on an open-frame rack.

### CROSS-REFERENCE TO RELATED APPLICATION

This application is a continuation-in-part application of co-pending U.S. patent application Ser. No. 15/091,595, filed Apr. 6, 2016, for “Microchip for Audio Enhancement Processing,” which claims the priority benefit of now expired U.S. Provisional Patent Application Ser. No. 62/143,253, filed Apr. 6, 2015, for “Microchip for Audio Enhancement Processing,” the entire disclosures of which are hereby incorporated by reference in their entirety including the drawings.

### BACKGROUND OF THE INVENTION

### 1. Field of the Invention

The present invention pertains to audio processing units. More particularly, the present invention pertains to audio processing units which can be incorporated into an audio processing unit. Even more particularly, the present invention pertains to audio processing units for processing an inputted audio signal via an audio processing unit.

### 2. Description of Related Art

A rack frame is a standardized frame or enclosure used for arranging multiple electronic equipment modules usually in a vertically mounted fashion. Modules or “units” to be mounted within the rack frame are typically 19 inches wide and include an “ear” on each side of the unit to facilitate mounting the unit to the frame with the use of any suitable fasteners. These frames are typically found in computer server rooms, audio recording studios, scientific labs, and the like. As such, common units include, firewalls, switches, audio processors, and the like. The height of a units is measured in “rack units,” abbreviated as RU or U. One RU is equal to 1.75 inches. The height of the unit is directly related to the amount of equipment stored within the unit. A unit may have a width less than 19 inches and not be mounted to both sides of the rack. However, the unit will typically require a larger height in order to adequately support the weight of the unit.

Audio processing units generally include any number of inputs and outputs for receiving a raw audio signal and transmitting a processed audio signal, respectively. In adjusting the signal received by the audio processing unit, the unit includes a plurality of controls for adjusting different levels of volume and frequencies and control equalizers, etc. However, the processing capabilities of the audio processing unit is directly limited by the digital signal processor or DSP within the unit itself. As a result, many commercially available racks for processing an audio signal are limited in their ability to master or remaster an inputted audio file.

Therefore, there is an ongoing need for an audio signal processing unit which provides improved audio mastering capabilities and allows for user controlled customization of the mastered audio signal.

It is to this to which the present invention is directed.

### SUMMARY OF THE INVENTION

The present invention provides an audio processing unit comprising a sound enhancement microchip having software embedded therein. Preferably, the audio processing unit is incorporated into a frame rack.

The unit includes at least one input for receiving an originally unprocessed audio signal and at least one output for transmitting the resulting processed audio signal to a source for review and/or storage.

The software embedded in the microchip improves the quality of the audio signal being sent to the unit prior to any user modification. The microchip operates by duplicating the inputted audio signal, splitting the duplicated signal into at least two exact duplicates of the original inputted signal, layering the signals, processing the layers, and recombining the layers to provide an enhanced or processed audio signal.

The circuitry associated with the microchip can be provided as a single integrated circuit or a microcircuit. All processing is done in the digital domain.

The microchip is interposed within the existing circuitry of the unit, at a convenient point, prior to the delivery of the audio signal to the user.

Thereafter, the processed audio signal is available for further user processing by utilizing any of the controls on the unit.

For a better understanding of the present invention, reference is made to the accompanying drawing and detailed description. In the drawing, like reference characters refer to like parts through the several views, in which:

### BRIEF DESCRIPTION OF THE DRAWING

FIG. 1a is a front view of a mountable audio processing unit in accordance with the present invention which includes a sound enhancement microchip disposed therein;

FIG. 1b is a rear view of the audio processing unit hereof;

FIG. 2 is a flow chart illustrating the manner by which an audio signal is enhanced in accordance with the present invention;

FIG. 3 is a schematic block diagram of a circuit having three branches and which is suitable for use in at least one configuration of the microchip of FIG. 2;

FIG. 4 is a schematic block diagram of a configuration of a circuit branch suitable for use in the circuit represented by FIG. 3;

FIG. 5 is a schematic block diagram of an equalizer EQ1 (DMG/CRBQ) suitable for use in the circuit represented by FIG. 4 when the circuit represented by FIG. 4 is a first circuit branch;

FIG. 6 is a schematic block diagram of an equalizer EQ2 (DMG/CRBQ) suitable for use in the circuit represented by FIG. 4 when the circuit represented by FIG. 4 is a second circuit branch;

FIG. 7 is a schematic block diagram of an equalizer EQ3 (DMG/CRBQ) suitable for use in the circuit represented by FIG. 4 when the circuit represented by FIG. 4 is a third circuit branch; and

FIG. 8 is a schematic block diagram of an output circuit suitable for use in the circuit represented by FIG. 3.

### DETAILED DESCRIPTION OF THE INVENTION

The present invention is directed to an audio processing unit including a sound enhancing microchip disposed therein. It is to be understood that the audio processing unit hereof has particular utility in professional recording studios, broadcast facilities, and other audio processing environments.

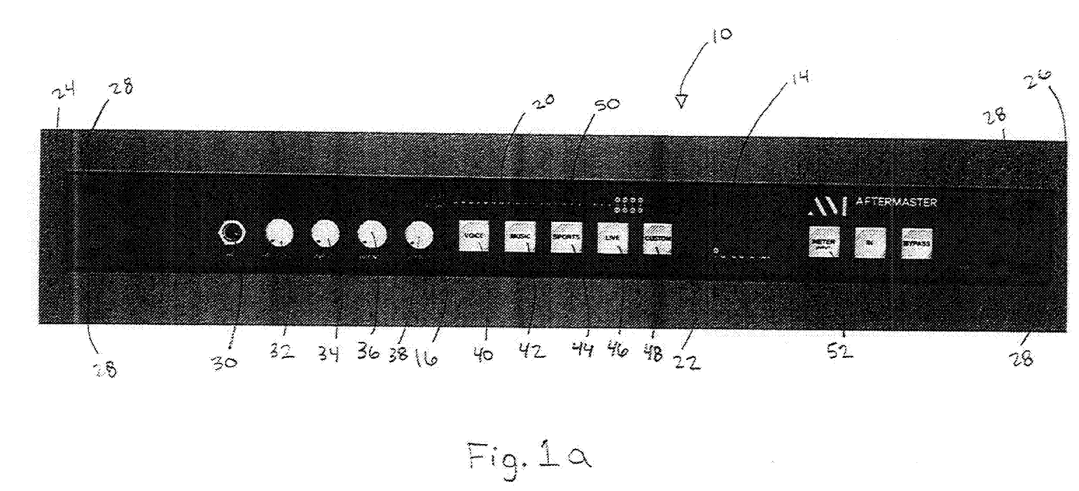

Now, and with reference to FIGS. 1a and 1b, as depicted therein, the present invention provides an audio processing unit 10 having a sound enhancing microchip 12 disposed therein.

It is to be understood that the audio processing unit 10 comprises an enclosed housing 14 having a front surface 16, a rear surface 18, a top surface 20, a bottom surface 22, and a pair of sides 24, 26. Preferably, the housing 14 is dimensioned to fit within a standard open-frame rack (not shown). Thus, the housing 14 includes a plurality of apertures 28 formed in the corners of the front surface 16 of the housing 14 for allowing suitable fasteners (not shown), such as screws or the like, to mount the unit 10 to the rack.

The unit 10 may include a plurality of knobs, buttons, meters, plugins, and other suitable controls for allowing user adjustment of a processed audio signal.

As shown in FIG. 1a, the front surface 16 of the housing 14 includes adjustment members, such as rotatable knobs for controlling the volume and levels of the processed audio signal. Specifically, the housing 14 includes an audio output 30 for connecting headphones or other audio devices, an output volume knob 32 to adjust the volume of the audio output 30, an input volume knob 34 for adjusting the volume of the audio signal going into the unit 10, a blend knob 36 which allows the user to “blend” the unprocessed audio signal with the processed audio signal, and an output or “make-up” gain control knob 38 for adjusting the gain of the resulting audio signal. Although the drawing shows four adjustment members, it is to be understood that the unit 10 is not so limited.

Referring, again, to FIG. 1a the housing 14 also includes a plurality of means for actuating preset equalizer settings, such buttons corresponding to preset equalizer settings, including a voice button 40, a music button 42, a sports button 44, a live button 46, and a custom button 48. The custom button 48 may be preset during manufacturing or initial setup of the unit 10 or, alternatively, may be programmable by the user based on his or her desired preferences.

Preferably, the suitable sample rates that work with the unit 10 are 32 k, 44.1 k, 48 k, 88.2 k, and 96 k. Alternatively, these sample rates can be selected in combination with the equalizer settings to provide the desired audio output.

The housing 14 also includes an RMS meter 50. The RMS meter 50 shows the input and output levels of both left and right channels. A meter (input) button 52 is included for selecting between two metering options. Additionally, a bypass button 54 is included on the housing 14 which will output the original, unprocessed audio source. In the case of a power failure or when the unit 10 is powered off, all digital and analog input and outputs will automatically be bypassed. Such RMS meters are well known and commercially available.

It is to be understood that any other controls other than those specifically described above may be included on the housing for allowing various modifications and/or adjustments to be made to the processed audio signal.

The unit 10 also includes a plurality of different inputs and outputs for receiving and transmitting the audio signal to a variety of acceptable audio sources. As shown in FIG. 1b, the rear surface 18 of the housing 14 includes a plurality of different in and out options which ordinarily are active at all times. Typically, and as illustrated, the in and out options include XLR(+4 dBU) 56, SPDIF 58, RCA(−10 dBu) 60, Optical 62, and AES/EBU 64. A clock input 66 may also be provided.

The unit 10 also includes internet connection capability via an ethernet cable (not shown). As such, the unit 10 includes an ethernet input 68. This allows the settings on the unit 10 to be changed remotely when connected to the internet. Alternatively, permissions on the unit 10 may be restricted such that the settings on the unit 10 can only be modified by designated persons via the internet connection.

Preferably, the unit 10 includes an external power supply (not shown) as well as the ability to run redundant power via the XLR input 56 or, alternatively, an AWG universal power input 70.

As noted above and in accordance herewith, the unit 10 has a microchip 12 included therewith. The chip 12 is a digital signal processor (DSP) for processing the inputted audio signal prior to further processing by the user. The microchip 12 is directly connected to the existing circuitry of the unit 10 and operates to master or remaster the inputted audio signal once received by the unit 10.

It is to be understood that the circuity of the unit 10 and the microchip 12 are each in electrical communication with one another by any suitable wiring and configuration well known to one of ordinary skill in the art.

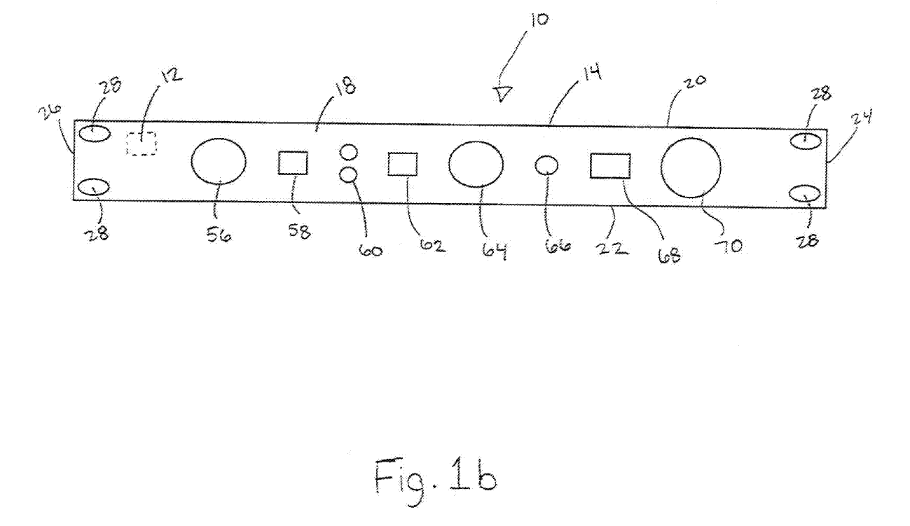

Referring now to FIGS. 2-8, the audio signal being transmitted into the unit 10 is processed by the sound enhancing microchip 12. At the outset, it is to be understood that the term “layer,” as used herein, means a copy of a signal that is layered or placed, at least in part, on top of an initial signal or a duplicate of that initial signal. Moreover, any reference to an audio processing equipment, such as an equalizer, audio leveler, compressor/expander, fader, limiter, volume control, multiplier, level detector, and the like, is to be understood as referring to corresponding software providing equivalent functionality and embedded within the microchip 12.

According to the present invention, generally, sound enhancement is achieved by the microchip 12 receiving the audio signal from a circuit board 72 and creating both an exact duplicate of that initial signal and at least one secondary signal. The at least one secondary signal is an exact duplicate of the initial signal, thereby creating at least two layers therefrom. Optimally, each of the layers is processed within the microchip 12 by an equalizer calibrated at a selected frequency. The frequencies of each layer can either be the same or different from each other.

At least one of the layers, preferably at least two layers, is processed. Once the at least one layer is processed, the signals are layered and passed through an equalizer, their volumes adjusted, passed through a leveler and, lastly, a master fader of the layered signals are being combined via a combining bus, as further discussed below.

As shown in FIG. 2, the input signal 220 from the circuit board 72 is processed at 221. Typically, the volume level is adjusted to about 8 to 16 dB, prior to being processed. Alternatively, the signal volume may be raised, lowered, or adjusted at any point in the enhancement process by adjusting the volume on the unit 10.

Initially, an equalizer 222 either filters out any unwanted frequencies or boosts or adds frequencies in the duplicate. As noted above, the output from the equalizer 222 is split into at least one copy of the initial signal and one secondary signal, which is a duplicate of the signal of the initial signal. The signals are then processed and layered. This is shown as Layer 1, denoted at 223, and Layer 2, denoted at 233. Frequencies in the range of 125 to 400 cycles per second can be adjusted to any desired levels or volume, any subsequent layers will be affected by this reduction. The use of the equalizer 222 can, if desired, be eliminated, but has found to be important in facilitating processing of the signal during subsequent processing of each of the layers 223, 233.

As described below, if desired, more than two layers can be produced such as Layer 3, Layer 4, etc. which can be processed in the same manner shown in FIG. 2.

During the processing of Layer 1 223, Layer 1 233 is first adjusted in volume by fader 223a; processed by an equalizer 224; adjusted in volume at 225 via an equalizer volume control; compressed by compressor 226; adjusted in volume by a compressor volume control 227; processed by compressor/expander 228; has its volume once again adjusted by the fader at 229; combined with the secondary layer 260; processed by equalizer 230; adjusted in volume, again, by an equalizer volume control at 230a; and, lastly, processed by limiter 241 where the layered signal is sent to the microchip output 38 through master fader 241a and output 241b.

Layer 2 233 is processed in the same manner as Layer 1 223 and, therefore, Layer 2 is first adjusted in volume by fader 233a; processed by equalizer 234; adjusted in volume by the equalizer volume control at 235; compressed by compressor 236; adjusted in volume by the compressor volume control at 237; processed by compressor/expander 238; adjusted in volume again at the fader 239; merged atop or layered atop Layer 1 at a combining bus layered signal 260 prior to entry into the equalizer 230 where the merged layers are processed by equalizer 230; undergoes final adjustment in volume 230a by the equalizer volume control; processed by limiter 241 and outputted to the microchip output 38 through master fader 241a and output at 241b.

More particularly, just prior to entry into the equalizer 230, the combining bus 260 is used to layer the incoming signals, followed by the layered signals being processed together. The output 241b is thus the layered enhanced audio to be sent to the handset 26.

Synchronization of the processing of all layers is important. The time required for each layer 223, 233 to pass through its respective processing is substantially equivalent so that the signal of each layer 223, 233 takes substantially the same amount of time to pass through its processing, merge at the combining bus 260, and be outputted as a single layered audio signal at 241b. Optimally, processing is done at the same time.

The signals produced by each layer 223, 233 can be equal in loudness, but in most cases, usually Layer 1 223 is louder than Layer 2 233. For example, Layer 1 223 can have its bass minimized while emphasizing and processing higher frequencies. Similarly, Layer 2 233 can have its higher frequencies minimized while emphasizing bass frequencies or vice versa.

If the bass frequencies in the initial audio signal are weak, processing of Layer 2 233 can increase the loudness of the bass frequencies so that when the processed layers 223, 233 are joined at the combining bus 260, prior to steps 230, 230a, 241, 241a, and 241b, the resulting audio signal increases a bass component with a greater volume and presence than is the case in the initial audio signal or vice versa.

Layer 1 223 and Layer 2 233, each, ordinarily, focuses on a band of frequencies that is different from any band of frequencies focused in the other layer. The frequencies that are not being focused on in one layer are being focused on in another layer and complement each other.

After enhancement, the dynamic range appears to be retained.

When a compressor, such as at 226, 236, is utilized, the threshold setting is typically adjusted to the user's preference. Preferably, each layer 223, 233 is processed with the equivalent of at least one piece of enhancement equipment simultaneously. While the processing shown in FIG. 2 is preferred in practicing the present invention, it is essential that the signal pass through two pieces of equipment, e.g., compressor/expander and fader, etc. As used herein, the term “multiple pieces of equipment” is intended to include the equivalent of a single piece of electronic equipment which provides one or more multiple functions, e.g. compressing, volume reduction, enhancements, equalizing, etc.

In general, the particular frequencies that Layer 1 223 or Layer 2 233 emphasizes will experience an increase in volume compared to their volume levels when the frequencies first enter the onset of the layering process from the equalizer 222. The signal processing is akin to that disclosed in the aforementioned co-pending U.S. Patent Application.

The sound enhancement may be accomplished through portable circuitry such as on a pc board, or may be incorporated into a microchip such as disclosed in the aforementioned co-pending U.S. Patent Application or in a software app.

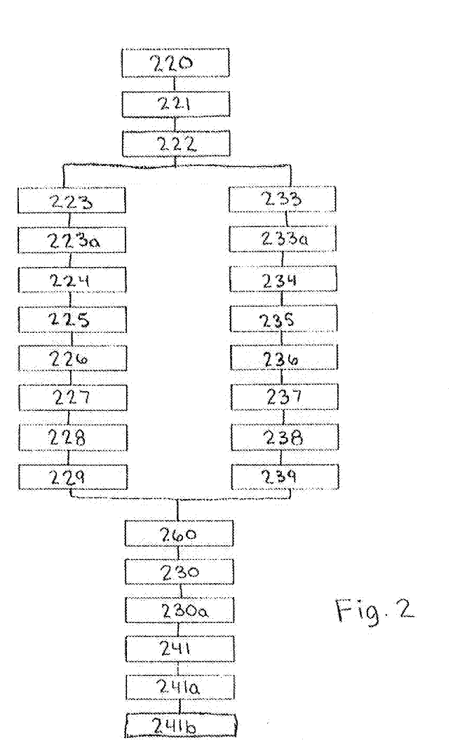

As disclosed in the co-pending application and with reference to FIGS. 3-8, there is shown a circuit 400 or other suitable apparatus for use in sound enhancement, which is embedded in the microchip 12 of the present invention. This circuit 400 may be provided as a single integrated circuit or micro circuit. Preferably, all processing is done in the digital domain. Generally, the input signal comprises a 16-bit input and 16-bit output with a sample rate of 48,000 samples per second, although these particular specifications are optional and not necessary for practicing the invention. In other embodiments, other specifications may be used.

FIG. 3 illustrates a schematic block diagram of the circuit 400 having three branches and which is suitable for use in at least one configuration of the microchip 12. To adjust the volume level, the input signal 220 is passed through an electronic gain control (e.g., a multiplier circuit) 221, which acts as a volume control. An equalizer 222 either filters out any unwanted frequencies or boosts or adds frequencies in the duplicate signal. Here, an equalizer 222 comprises an LF circuit 402. The output of the equalizer 222 is processed by audio layer processing circuitry 408.

In the embodiment represented by FIG. 3, three separate layers, denoted at Layer 1 223, Layer 2 233, and Layer 3 403 are provided. It will be understood that the number of layers provided may vary in different embodiments. The input of each of the three layers 223, 233, 403 is split off the output of equalizer 222 and the output of the three layers 223, 233, 403 is added together by adder accumulator 416. The output of adder accumulator 416 is provided to output circuitry 418, where, among other things, the output gain is controlled by a signal 420 and the output is provided at 241B.

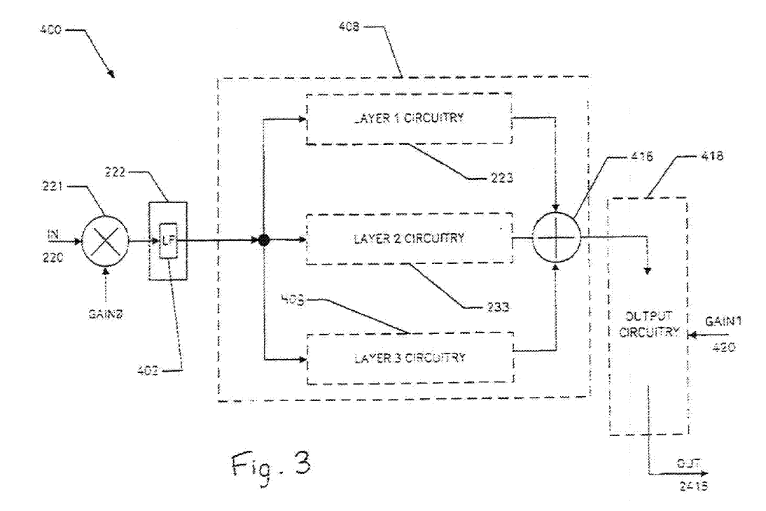

Referring now to FIG. 4, typical circuitry 500 for either Layer 1 223, Layer 2 233, and Layer 3 403 comprises an electronic gain level control or multiplier 502 denoted at GAINLN_1, where GAINLN_1 varies (or can vary) depending upon which layer N is being represented by circuitry 500. The output of gain level control or multiplier 502 is passed to an equalizer circuit EQN(DMG/CRBG) 504, which varies (or can vary) depending upon the layer N being represented by circuitry 500. The output of equalizer circuit 504 is passed through a compressor 506 to set a maximum volume. Compressor 506 comprises a gain level control or multiplier 508 and a level detector 510, both of which are fed a signal split from the output of equalizer circuit 504. The output of level detector 510 is used as the input of input/output lookup table (I/O LUT) 512, which provides a gain control for gain level controller or multiplier 508, so that the output of the gain level controller or multiplier 508 does not exceed a certain maximum level.

The contents of I/O LUT 512 may vary depending upon which layer N is being represented by circuitry 500. The compressed output of gain level control or multiplier 508 is then applied to a compressor/expander 514, wherein the same compressed output is applied as an input after splitting to both gain level control or multiplier 516 and band level detector 518. The output of band level detector 518 is applied to a gain LUT 520, which provides a gain control input for gain level control or multiplier 516. The circuitry of band level detector 518 and/or gain LUT 520 may vary depending upon which layer N is represented by circuitry 500.

The output of compressor/expander 514 is provided as an input to gain level control or multiplier 522, which, together with applied signal GAINLN_2, acts as an overall gain control for Layer N.

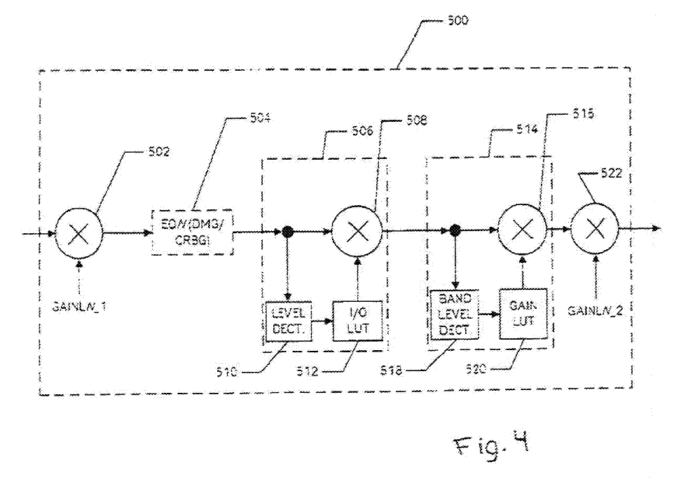

In the embodiment represented by FIG. 5, for layer N=1, EQN(DMG/CRBG) 500 comprises an EQ1 (DMG/CRBG) 4-section BQ 600, in which the input signal from gain level control or multiplier 502 is applied to a circuit comprising a series connection of HP 602, LMF 604, MF 606, and HF 608.

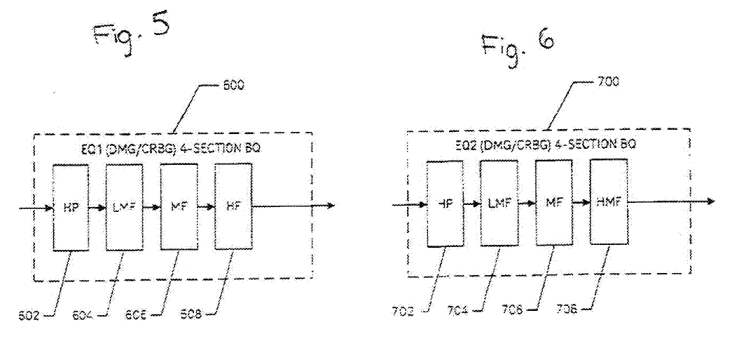

Similarly, in the embodiment represented by FIG. 6, layer N=2, EQN(DMG/CRBG) 500 comprises an EQ2 (DMG/CRBG) 4-section BQ 700, in which the input signal from gain level control or multiplier 502 is applied to a circuit comprising a series connection of HP 702, LMF 704, MF 706, and HF 708.

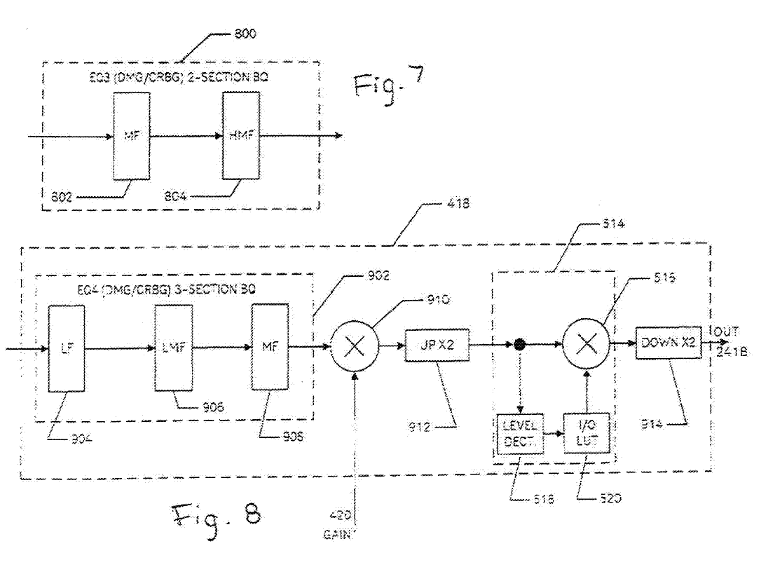

Likewise, in the embodiment represented by FIG. 7, layer N=3, EQN(DMG/CRBG) 500 comprises an EQ2 (DMG/CRBG) 4-section BQ 800, in which the input signal from gain level control or multiplier 502 is applied to a circuit comprising a series connection of MF 802 and HMF 804.

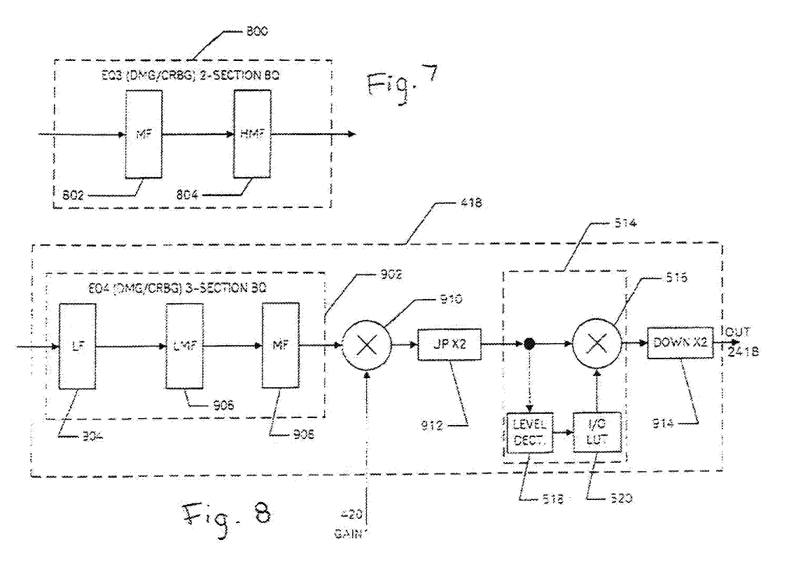

Further, in the embodiment represented by FIG. 8, the sum of the various layers N is passed through output circuitry 418. The input signal of output circuitry 418 is passed through EQ4(DMG/CRBG) 500, which comprises an EQ4 (DMG/CRBG) 3-section BQ 902. The output of EQ4 (DMG/CRBG) 902 is applied to an overall gain controller or multiplier 910, which uses signal GAIN1 420 to control the output level of the combined, processed signal after all the levels are combined. The output of overall gain controller or multiplier 910 is then digitally upconverted using UP X2 912 and applied as input to compressor/expander 514. The output of overall gain controller or multiplier 910 is split and applied to a gain controller or multiplier 516 and a level detector 518. The output of level detector 518 is applied to I/O LUT 520 to obtain a gain level for gain controller or multiplier 910. (Note that the level detector 518 and the I/O LUT 520 do not necessarily have the same specifications or content as those described in conjunction with FIG. 4.) The output of compressor/expander 514 is then down converted by DOWN X2 914, and the overall output of the circuit appears at output 241B.

After the sound enhancement processing is completed within the circuit 400 of the microchip 12, the layered audio signal is transmitted through the remaining circuitry of the unit 10 in order to be further processed by the user by utilizing any one or a combination of the knobs and buttons on the housing 14.

While the unit 10 disclosed hereinabove is described as being mountable on a frame rack, it is to be understood that the unit 10 may be situated on any surface without deviating from the scope of the present invention.

From the above, it is to be appreciated that defined herein is a new and unique mountable audio processing unit having an audio enhancing microchip disposed therein for processing an audio signal and improving the quality of the audio signal prior to being delivered to the user for further processing.

Having thus described the invention, what is claimed is:

1. An audio processing rack comprising:
an audio processing unit having a microchip embedded therein for processing an inputted audio signal, the audio processing unit including:
an enclosed housing having a plurality of controls for allowing user adjustment or modification of the inputted audio signal, the microchip being disposed within the housing and in electrical communication with the plurality of controls, the microchip including circuity for initially processing the inputted audio file by performing the following steps:
(a) reducing the volume of the inputted audio signal;
(b) processing the reduced volume signal through an equalizer;
(c) duplicating the inputted audio signal to provide at least one exact copy of the audio signal, the audio signal defining a first signal layer, the at least one exact copy defining an at least one exact equivalent secondary signal layer;
(d) separating the inputted audio signal and the at least one exact equivalent secondary signal, each as a whole into two separate identical signal layers;
(e) reducing the amplitude in each of the signal layers;
(f) synchronously processing at the same time and without any time delay between the signals, the identical separate signal layers by:
(i) sequentially processing each of the signal layers with at least two simulated pieces of equipment selected from the group consisting of a limiter, an expander, a compressor, and an equalizer, either the original or the at least one equivalent secondary signal layers being processed within a first range of frequencies and the other of the original or the at least one equivalent secondary signal layer within a different range of frequencies;
(ii) reducing the volume of each of the signal layers as a whole when each signal layer is transmitted from one of the above pieces of equipment to another of the above pieces of equipment;
(g) merging the processed signal layers at a combining bus; and
(h) processing together simultaneously the merged signal layers through at least an equalizer, a limiter, and a master fader which is then outputted,
wherein the time for processing each of the signal layer is the same, and further wherein the merged signal layers are then outputted to a user for further processing on the audio processing unit.

2. The audio processing rack of claim 1, wherein the microchip comprises:
(a) means for inputting an original audio file into a signal divider and for outputting the original audio file and at least one exact duplicate of the original audio file;
(b) a first equalizer in communication with the means for inputting and outputting, the equalizer simultaneously and at the same time lowering the volume of the original audio file and the at least one exact duplicate;
(c) means for processing each of the audio files outputted from the first equalizer simultaneously and at exactly the same time without any time delay between the signals, the means for processing comprising:
(i) a first fader in communication with the first equalizer;
(ii) a second equalizer receiving the output from the first fader;
(iii) means for lowering the volume of an output from the first fader;
(iv) means for lowering the volume of the output from the compressor, the compressor having an output;
(v) an expander which receives the output from the means for lowering the volume of the output from the compressor, the expander having an output;
(vi) means for lowering the volume of the output from the expander;
(vii) a second fader receiving the lowered volume from the expander;
(viii) a combining bus for merging the output from both the first fader and the second fader;
(ix) a second equalizer for processing the merged signals;
(x) a second limiter, the output from the second limiter being in communication with the second equalizer and outputting to a master fader; and
(xi) a master fader for outputting the signal from the master fader.

3. The audio processing rack of claim 1, wherein the enclosed housing is removably mountable to the rack.
